(19) United States
(12) Patent Application Publication
(10) Pub. No.: US 2026/0214794 A1
(43) Pub. Date: Jul. 23, 2026

(54) METALLIZED CERAMIC CIRCUIT BOARD AND MANUFACTURING METHOD THEREOF

(71) Applicant: TONG HSING ELECTRONIC INDUSTRIES, LTD., Taoyuan City (TW)

(72) Inventors: YI-YUAN LIN, Taoyuan City (TW); SHIH-HAN WU, Taipei City (TW); JIAN-YU SHIH, Taoyuan City (TW)

(21) Appl. No.: 19/372,219

(22) Filed: Oct. 28, 2025

Related U.S. Application Data
(60) Provisional application No. 63/747,894, filed on Jan. 22, 2025.

(30) Foreign Application Priority Data
Jul. 9, 2025 (TW) 114125898

(51) Int. Cl. H05K 1/03; H05K 1/02; H05K 3/00; H05K 3/24

(52) U.S. Cl. CPC H05K 1/0306; H05K 1/0201; H05K 1/0271; H05K 3/0026; H05K 3/0094; H05K 3/241; H05K 2201/09527; H05K 2201/09618; H05K 2201/09827

(57) ABSTRACT

A metallized ceramic circuit board and a manufacturing method thereof. The metallized ceramic circuit board includes a ceramic substrate, a seed layer formed on the ceramic substrate, and a patterned circuit formed on the seed layer. The ceramic substrate has a first surface, a second surface being opposite to the first surface, a plurality of first blind vias recessed in the first surface, and a plurality of second blind vias recessed in the second surface. Each of the second blind vias and one of the first blind vias are in spatial communication with each other to be jointly defined as a thru-hole, and respectively have two truncated shapes that are tapered along a direction approaching each other. The seed layer covers hole walls of the thru-holes, and the patterned circuit is formed on the seed layer and fully filled in the thru-holes in a direct plated copper manner.

### CROSS-REFERENCE TO RELATED PATENT APPLICATION

This application claims the benefit of priority to Taiwan Patent Application No. 114125898, filed on Jul. 9, 2025. The entire content of the above identified application is incorporated herein by reference.

This application claims the benefit of priority to the U.S. Provisional Patent Application Ser. No. 63/747,894, filed on Jan. 22, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a metallized ceramic circuit board and a manufacturing method thereof.

### BACKGROUND OF THE DISCLOSURE

A conventional circuit board is provided by using a silicon substrate or a glass substrate, so that heat-dissipation and bending resistance of the conventional circuit board are limited and difficult to be increased by the silicon substrate or the glass substrate.

### SUMMARY OF THE DISCLOSURE

In response to the above-referenced technical inadequacies, the present disclosure provides a metallized ceramic circuit board and a manufacturing method thereof for effectively improving on the issues associated with conventional circuit boards.

In order to solve the above-mentioned problems, one of the technical aspects adopted by the present disclosure is to provide a manufacturing method of a metallized ceramic circuit board, which includes a first drilling step, a second drilling step, a formation step, a patterning step, and a direct plated copper (DPC) step. The first drilling step is implemented by laser-drilling a first surface of a ceramic substrate to form a plurality of first blind vias spaced apart from each other. Each of the plurality of first blind vias has a truncated shape that is tapered in a direction away from the first surface. The second drilling step is implemented by laser-drilling a second surface of the ceramic substrate to form a plurality of second blind vias that are spaced apart from each other and that respectively correspond in position to the plurality of first blind vias. Each of the plurality of second blind vias has a truncated shape that is tapered in a direction away from the second surface, and each of the plurality of second blind vias and a corresponding one of the plurality of first blind vias are in spatial communication with each other to be jointly defined as one of a plurality of thru-holes. The formation step is implemented by forming a seed layer on the first surface, the second surface, and a plurality of hole walls respectively defining the plurality of thru-holes. The patterning step is implemented by respectively forming a first shielding layer and a second shielding layer on two opposite sides of the seed layer. Moreover, a part of the seed layer formed on the plurality of hole walls is exposed from the first shielding layer and the second shielding layer. The DPC step is implemented by electroplating the part of the seed layer to form a patterned circuit.

In order to solve the above-mentioned problems, another one of the technical aspects adopted by the present disclosure is to provide a manufacturing method of a metallized ceramic circuit board, which includes a first drilling step, a second drilling step, a formation step, a direct plated copper (DPC) step, a patterning step, and an etching step. The first drilling step is implemented by laser-drilling a first surface of a ceramic substrate to form a plurality of first blind vias spaced apart from each other. Each of the plurality of first blind vias has a truncated shape that is tapered in a direction away from the first surface. The second drilling step is implemented by laser-drilling a second surface of the ceramic substrate to form a plurality of second blind vias that are spaced apart from each other and that respectively correspond in position to the plurality of first blind vias. Each of the plurality of second blind vias has a truncated shape that is tapered in a direction away from the second surface, and each of the plurality of second blind vias and a corresponding one of the plurality of first blind vias are in spatial communication with each other to be jointly defined as one of a plurality of thru-holes. The formation step is implemented by forming a seed layer on the first surface, the second surface, and a plurality of hole walls respectively defining the plurality of thru-holes. The DPC step is implemented by electroplating the seed layer to form a metal layer that is filled in an entirety of each of the plurality of thru-holes and that covers the first surface and the second surface. The patterning step is implemented by respectively forming a first shielding layer and a second shielding layer on two opposite sides of the metal layer. Moreover, a part of the metal layer filled in the entirety of each of the plurality of hole walls is covered by the first shielding layer and the second shielding layer. The etching step is implemented by etching another part of the metal layer not covered by the first shielding layer and the second shielding layer to retain the part of the metal layer, which is defined as a patterned circuit.

In order to solve the above-mentioned problems, yet another one of the technical aspects adopted by the present disclosure is to provide a metallized ceramic circuit board, which includes a ceramic substrate, a seed layer, and a patterned circuit. The ceramic substrate has a first surface and a second surface that is opposite to the first surface. The ceramic substrate has a plurality of first blind vias and a plurality of second blind vias. The first blind vias are recessed in the first surface and are spaced apart from each other. Each of the plurality of first blind vias has a truncated shape that is tapered in a direction away from the first surface. The second blind vias are recessed in the second surface and are spaced apart from each other. Each of the plurality of second blind vias has a truncated shape that is tapered in a direction away from the second surface, and each of the plurality of second blind vias is in spatial communication with one of the plurality of first blind vias to be jointly defined as one of a plurality of thru-holes. The seed layer covers and is formed on hole walls respectively defining the plurality of thru-holes. The patterned circuit is formed on the seed layer in a direct plated copper (DPC) manner and is filled in an entirety of each of the plurality of thru-holes.

Therefore, the metallized ceramic circuit board and the manufacturing method thereof provided by the present disclosure can use the ceramic substrate to be cooperated with the seed layer and the patterned circuit for replacing the conventional silicon substrate or the conventional glass substrate, thereby ensuring that the metallized ceramic circuit board can meet requirements of circuit layout and can effectively increase the heat-dissipation and bending resistance thereof.

Specifically, the metallized ceramic circuit board and the manufacturing method in the present disclosure can be provided with the ceramic substrate that has the first blind vias and the second blind vias, which are in cooperation with each other by having the truncated shapes, so as to enable the thru-holes having a high density arrangement to be formed in the ceramic substrate and enable the patterned circuit having a low line width and/or a low line spacing to be formed on the ceramic substrate.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a metallized ceramic circuit board according to a first embodiment of the present disclosure;

FIG. 2 is a schematic view showing a first drilling step of a manufacturing method of the metallized ceramic circuit board according to the first embodiment of the present disclosure;

FIG. 3 is a schematic view showing a second drilling step of the manufacturing method according to the first embodiment of the present disclosure;

FIG. 4 is a schematic view showing a formation step of the manufacturing method according to the first embodiment of the present disclosure;

FIG. 5 is a schematic view showing a patterning step of the manufacturing method according to the first embodiment of the present disclosure;

FIG. 6 is a schematic view showing a direct plated copper (DPC) step of the manufacturing method according to the first embodiment of the present disclosure;

FIG. 7 is a schematic view showing a DPC step of the manufacturing method according to a second embodiment of the present disclosure;

FIG. 8 is a schematic view showing a patterning step of the manufacturing method according to the second embodiment of the present disclosure;

FIG. 9 is a schematic view showing an etching step of the manufacturing method according to the second embodiment of the present disclosure; and

FIG. 10 is a schematic view showing a removing step of the manufacturing method according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

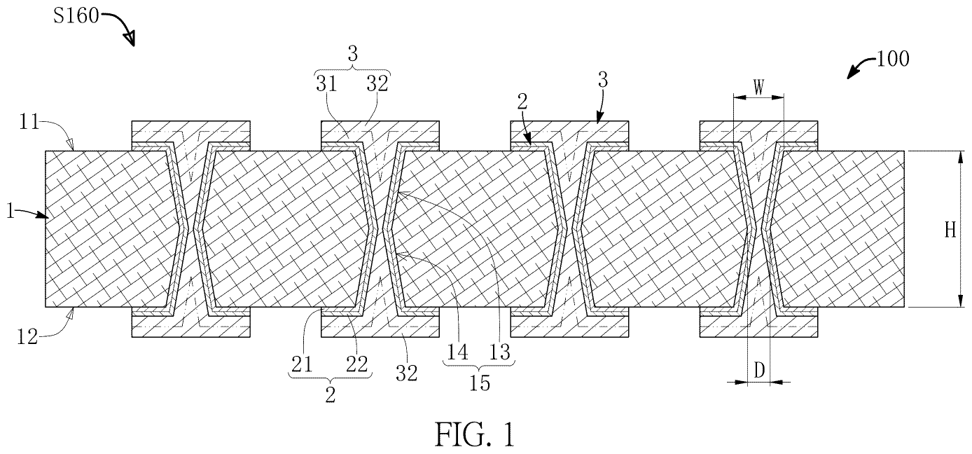

Referring to FIG. 1 to FIG. 6, a first embodiment of the present disclosure is provided. The present embodiment provides a metallized ceramic circuit board 100 and a manufacturing method thereof. The metallized ceramic circuit board 100 can be manufactured by implementing the manufacturing method, but the present disclosure is not limited thereto. For example, in other embodiments of the present disclosure not shown in the drawings, the metallized ceramic circuit board 100 can be manufactured by implementing other methods.

In order to clearly describe the present embodiment, the following description describes the metallized ceramic circuit board 100, and then describes the manufacturing method. As shown in FIG. 1, the metallized ceramic circuit board 100 in the present embodiment includes a ceramic substrate 1, a seed layer 2 formed on the ceramic substrate 1, and a patterned circuit 3 that is formed on the seed layer 2. In other words, any circuit board or any manufacturing method not using a ceramic substrate is different from the metallized ceramic circuit board 100 or the manufacturing method provided by the present embodiment.

The ceramic substrate 1 has a first surface 11 and a second surface 12 that is opposite to the first surface 11. The first surface 11 and the second surface 12 in the present embodiment are parallel to each other and are substantially in planar shape, but the present disclosure is not limited thereto. For example, in other embodiments of the present disclosure not shown in the drawings, at least one of the first surface 11 and the second surface 12 can be a non-planar shape according to practical requirements.

Moreover, the ceramic substrate 1 has a plurality of first blind vias 13 and a plurality of second blind vias 14. The first blind vias 13 are recessed in the first surface 11 and are spaced apart from each other, and the second blind vias 14 are recessed in the second surface 12 and are spaced apart from each other. Specifically, the first blind vias 13 respectively correspond in position to the second blind vias 14, and each of the second blind vias 14 is in spatial communication with a corresponding one of the first blind vias 13 to be jointly defined as one of a plurality of thru-holes 15.

It should be noted that the thru-holes 15 in the present embodiment are of substantially the same shape, and the first blind via 13 and the second blind via 14 of each of the thru-holes 15 are in a mirror-symmetrical arrangement, but the present disclosure is not limited thereto. For example, in other embodiments of the present disclosure not shown in the drawings, the thru-holes 15 can be of different shapes according to practical requirements; or, the first blind via 13 and the second blind via 14 of at least one of the thru-holes 15 can be of different shapes.

In the present embodiment, each of the first blind vias 13 has a truncated shape (e.g., a truncated cone shape) that is tapered in a direction away from the first surface 11, and each of the second blind vias 14 has a truncated shape (e.g., a truncated cone shape) that is tapered in a direction away from the second surface 12. Moreover, each of the thru-holes 15 has a depth H and a width W that corresponds to the first surface 11, and the depth H and the width W of each of the thru-holes 15 jointly define an aspect ratio (H/W) that is greater than or equal to 10.

Specifically, in each of the thru-holes 15, edges of the first blind via 13 and the second blind via 14 adjacent to each other are aligned and connected to each other, a connection region (e.g., the edges) of the first blind via 14 and the second blind via 15 has an aperture D that is within a range from 20 μm to 40 μm, and another aperture of the first blind via 14 corresponding to the first surface 11 (e.g., the width W of the thru-hole 15) is within a range from 50 μm to 70 μm, but the present disclosure is not limited thereto.

The seed layer 2 covers and is formed on hole walls of the thru-holes 15, a part of the first surface 11, and a part of the second surface 12, the latter two of which are adjacent to the hole walls. The hole wall of each of the thru-holes 15 is entirely covered by the seed layer 2, and the first blind via 13 and the second blind via 14 of each of the thru-holes 15 are maintained to be in spatial communication with each other when the seed layer 2 is formed.

Moreover, the patterned circuit 3 is formed on the seed layer 2 in a direct plated copper (DPC) manner and is filled in an entirety of each of the thru-holes 15. It should be noted that a portion of the patterned circuit 3 corresponding in position to any two of the thru-holes 15 can be connected or unconnected to each other according to practical requirements, and the present disclosure is not limited thereto.

In addition, the seed layer 2 in the present embodiment includes a copper alloy layer 21 (e.g., a titanium copper layer or a nickel copper layer) formed on the ceramic substrate 1 in a deposition manner and a copper layer 22 that is formed on the copper alloy layer 21 in a chemical plating manner, and the patterned circuit 3 is formed on the copper layer 22 in the DPC manner, but the present disclosure is not limited thereto.

In summary, the ceramic substrate 1 is provided with the first blind vias 13 and the second blind vias 14, which are in cooperation with each other by having specific shapes, so as to enable the thru-holes 15 having a high density arrangement (e.g., a pitch between central lines of any two of the thru-holes 15 adjacent to each other being able to be at least 90 μm) to be formed in the ceramic substrate 1 and enable the patterned circuit 3 having a low line width and/or a low line spacing (e.g., the line width and/or the line spacing being able to be at least 20 μm) to be formed on the ceramic substrate 1.

The structure of the metallized ceramic circuit board 100 is substantially described in the above description, and the following description describes the manufacturing method, that can be appropriately referred to the above description related to the metallized ceramic circuit board 100.

As shown in FIG. 1 to FIG. 6, the manufacturing method of the present embodiment sequentially includes a first drilling step S110, a second drilling step S120, a formation step S130, a patterning step S140, a direct plated copper (DPC) step S150, and a removing step S160. The following description describes each of the above steps, but the present disclosure is not limited thereto.

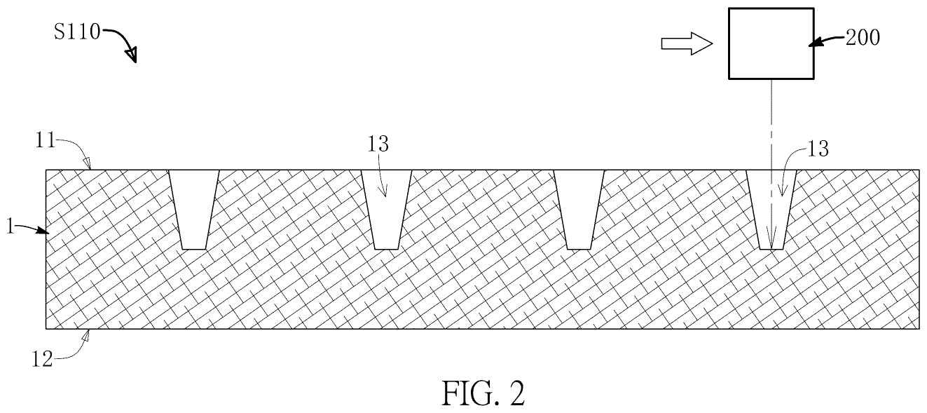

As shown in FIG. 2, the first drilling step S110 is implemented by laser-drilling a first surface 11 of a ceramic substrate 1 to form a plurality of first blind vias 13 spaced apart from each other by using a laser apparatus 200. Moreover, each of the first blind vias 13 has a truncated shape (e.g., a truncated cone shape) that is tapered in a direction away from the first surface 11.

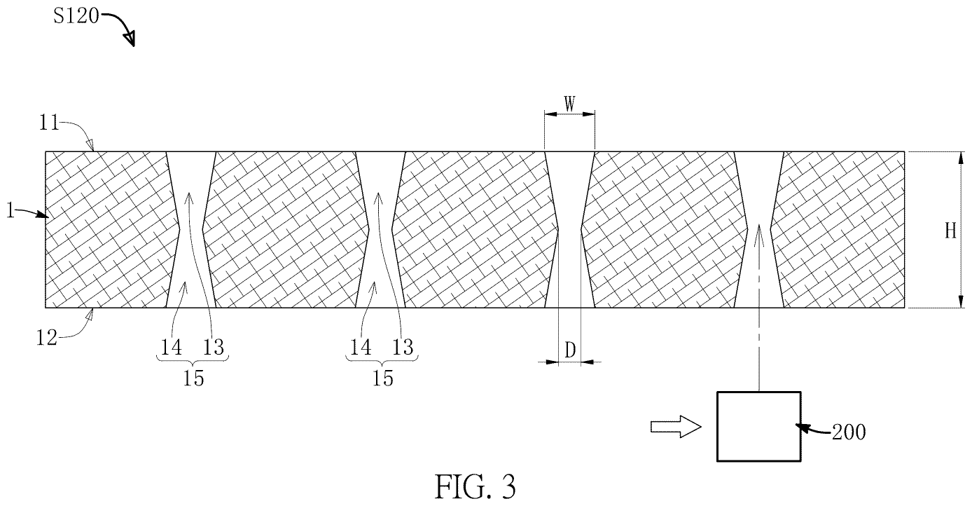

As shown in FIG. 3, the second drilling step S120 is implemented by laser-drilling a second surface 12 of the ceramic substrate 1 to form a plurality of second blind vias 14 that are spaced apart from each other and that respectively correspond in position to the first blind vias 13 by using the laser apparatus 200. Moreover, each of the second blind vias 14 has a truncated shape (e.g., a truncated cone shape) that is tapered in a direction away from the second surface 12, and each of the second blind vias 14 and a corresponding one of the first blind vias 13 are in spatial communication with each other to be jointly defined as one of a plurality of thru-holes 15.

Specifically, the first blind via 13 and the second blind via 14 of each of the thru-holes 15 in the present embodiment are in a mirror-symmetrical arrangement. Each of the thru-holes 15 has a depth H and a width W that corresponds to the first surface 11, and the depth H and the width W of each of the thru-holes 15 jointly define an aspect ratio that is greater than or equal to 10, but the present disclosure is not limited thereto.

It should be noted that the first drilling step S110 and the second drilling step S120 in the present embodiment are implemented in sequence by using the laser apparatus 200, but the present disclosure is not limited thereto. For example, in other embodiments of the present disclosure not shown in the drawings, the first drilling step S110 and the second drilling step S120 can be implemented by using two laser apparatuses 200, such that the implementation of the first drilling step S110 and the second drilling step S120 can be partially overlapped (i.e., a part of the first drilling step S110 and a part of the second drilling step S120 are implemented at the same time) for improving an overall operational efficiency.

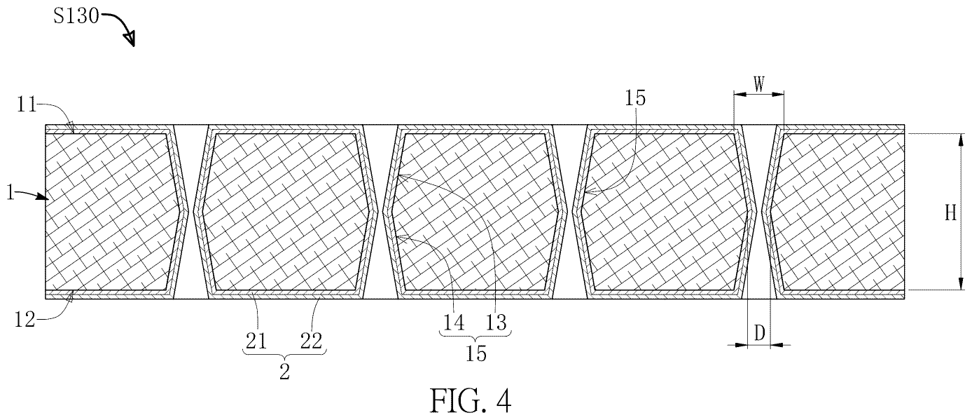

As shown in FIG. 4, the formation step S130 is implemented by forming a seed layer 2 on the first surface 11, the second surface 12, and a plurality of hole walls respectively defining the thru-holes 15. In the present embodiment, the formation step S130 sequentially includes a deposition step and a chemical plating step, but the present disclosure is not limited thereto. For example, in other embodiments of the present disclosure not shown in the drawings, the seed layer 2 can be formed in a single-layer structure by implementing a single step (or a single process).

Specifically, the deposition step is implemented by depositing a copper alloy layer 21 on the first surface 11, the second surface 12, and the hole walls of the thru-holes 15, and the implementation of the deposition step can be a physical vapor deposition (PVD), but the present disclosure is not limited thereto. Moreover, the chemical plating step is implemented by chemical plating the copper alloy layer 21 to form a copper layer 22, and the copper layer 22 and the copper alloy layer 21 are jointly defined as the seed layer 2.

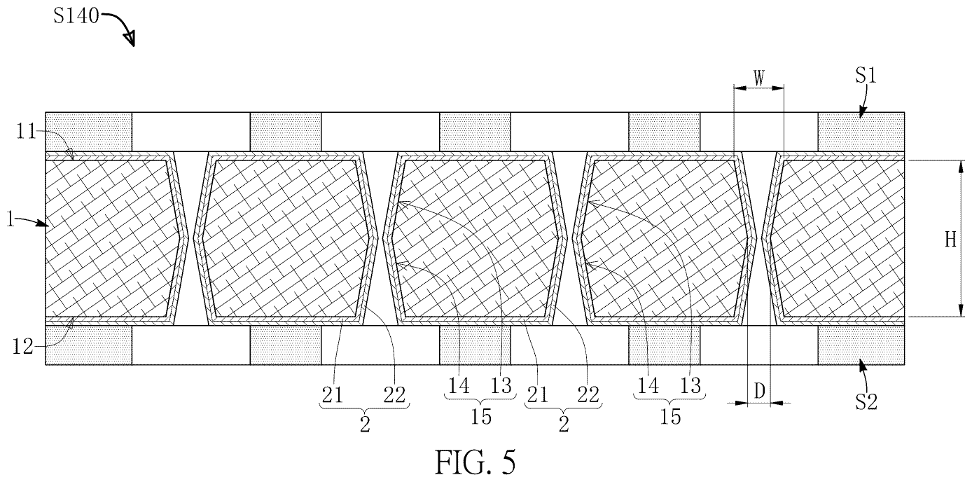

As shown in FIG. 5, the patterning step S140 is implemented by respectively forming a first shielding layer S1 and a second shielding layer S2 on two opposite sides of the seed layer 2 (e.g., the copper layer 22). Moreover, a part of the seed layer 2 formed on the hole walls is exposed from the first shielding layer S1 and the second shielding layer S2. It should be noted that another part of the seed layer 2 covered by the first shielding layer S1 and the second shielding layer S2 can be adjusted or changed according to practical requirements, and is not limited by the drawings of the present embodiment.

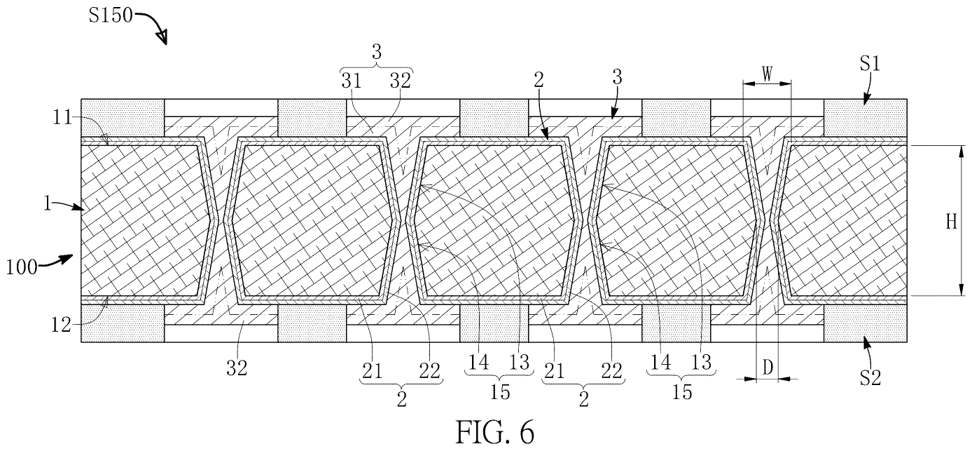

As shown in FIG. 6, the DPC step S150 is implemented by electroplating the part of the seed layer 2 (exposed from the first shielding layer S1 and the second shielding layer S2) to form a patterned circuit 3. In the present embodiment, the DPC step S150 sequentially includes a first copper plating step and a second copper plating step, but the present disclosure is not limited thereto. For example, in other embodiments of the present disclosure not shown in the drawings, the patterned circuit 3 can be formed in a single-layer structure by implementing a single step (or a single process).

Specifically, the first copper plating step is implemented by electroplating the part of the seed layer 2 (exposed from the first shielding layer S1 and the second shielding layer S2) to form a first conductive layer 31. Moreover, each of the thru-holes 15 is not fully filled with the first conductive layer 31, and the first blind via 13 and the second blind via 14 of each of the thru-holes 15 are not in spatial communication with each other through the first conductive layer 31. The second copper plating step is implemented by electroplating the first conductive layer 31 to form a second conductive layer 32, and the first conductive layer 31 and the second conductive layer 32 are jointly defined as the patterned circuit 3.

As shown in FIG. 1, the removing step S160 is implemented by removing the first shielding layer S1 and the second shielding layer S2, and removing the another part of the seed layer 2 (covered by the first shielding layer S1 and the second shielding layer S2) in an etching manner, thereby obtaining a metallized ceramic circuit board 100.

### Second Embodiment

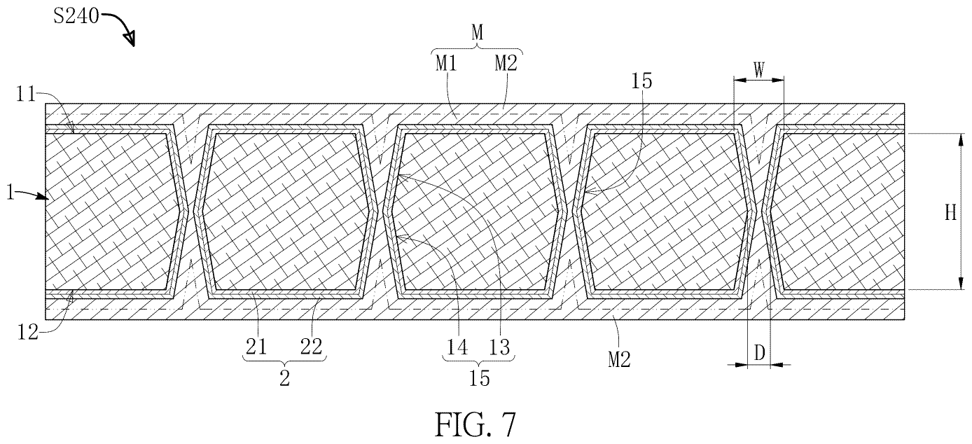

Referring to FIG. 7 to FIG. 10, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

The present embodiment provides a manufacturing method of a metallized ceramic circuit board sequentially includes a first drilling step, a second drilling step, a formation step, a direct plated copper (DPC) step S240, a patterning step S250, an etching step S260, and a removing step S270. The first drilling step, the second drilling step, and the formation step of the present embodiment are substantially identical to those of the first embodiment, and are not described again for the sake of brevity. The following description describes the DPC step S240, the patterning step S250, the etching step S260, and the removing step S270, but the present disclosure is not limited thereto.

As shown in FIG. 7, the DPC step S240 is implemented by electroplating the seed layer 2 to form a metal layer M that is filled in an entirety of each of the thru-holes 15 and that covers the first surface 11 and the second surface 12. In the present embodiment, the DPC step S240 sequentially includes a first copper plating step and a second copper plating step, but the present disclosure is not limited thereto. For example, in other embodiments of the present disclosure not shown in the drawings, the metal layer M can be formed in a single-layer structure by implementing a single step (or a single process).

Specifically, the first copper plating step is implemented by electroplating the seed layer 2 to form a first metal layer M1. Moreover, each of thru-holes 15 is not fully filled with the first metal layer M1, and the first blind via 13 and the second blind via 14 of each of the thru-holes 15 are not in spatial communication with each other through the first metal layer M1. The second copper plating step is implemented by electroplating the first metal layer M1 to form a second metal layer M2, and the first metal layer M1 and the second metal layer M2 are jointly defined as the metal layer M.

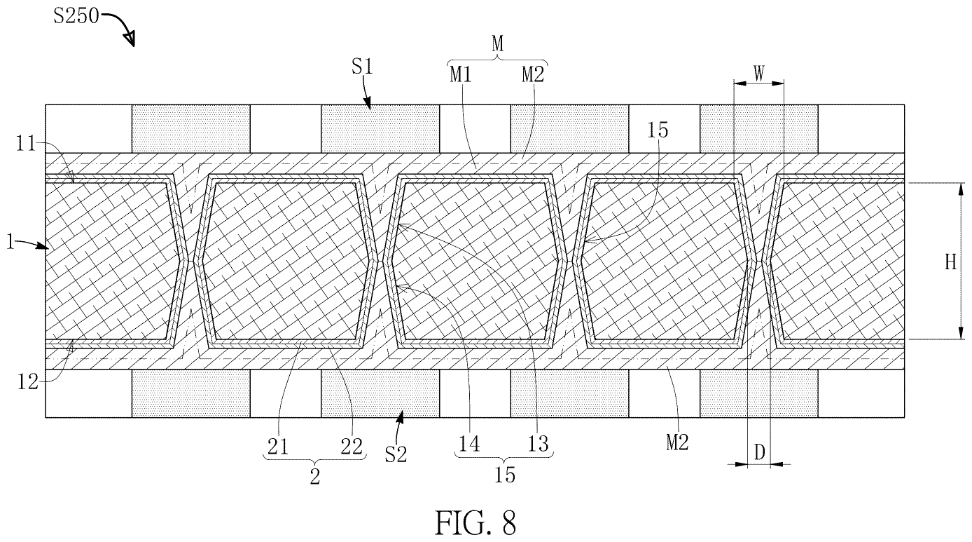

As shown in FIG. 8, the patterning step S250 is implemented by respectively forming a first shielding layer S1 and a second shielding layer S2 on two opposite sides of the metal layer M. Moreover, a part of the metal layer M filled in the entirety of each of the hole walls of the thru-holes 15 is covered by the first shielding layer S1 and the second shielding layer S2. It should be noted that another part of the metal layer M not covered by the first shielding layer S1 and the second shielding layer S2 can be adjusted or changed according to practical requirements, and is not limited by the drawings of the present embodiment.

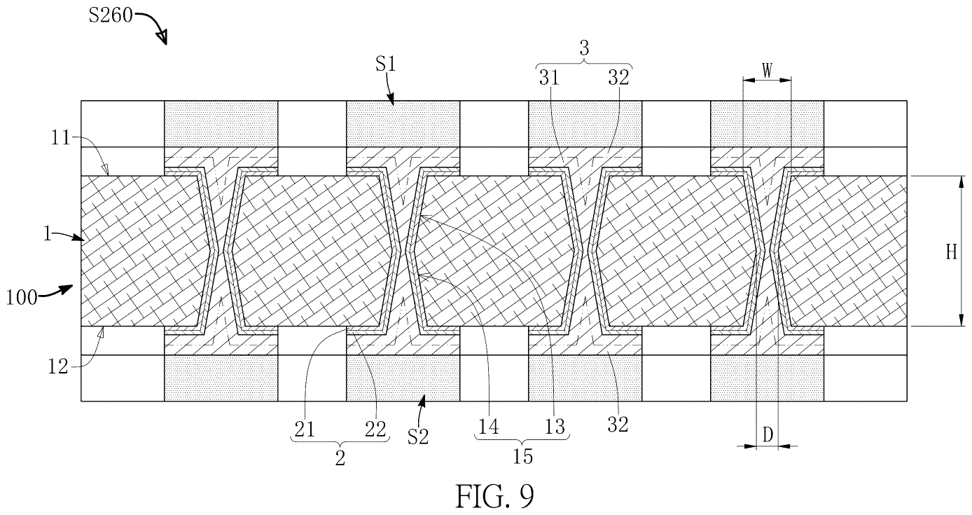

As shown in FIG. 9, the etching step S260 is implemented by etching the another part of the metal layer not covered by the first shielding layer S1 and the second shielding layer S2 to retain the part of the metal layer M, which is defined as a patterned circuit 3.

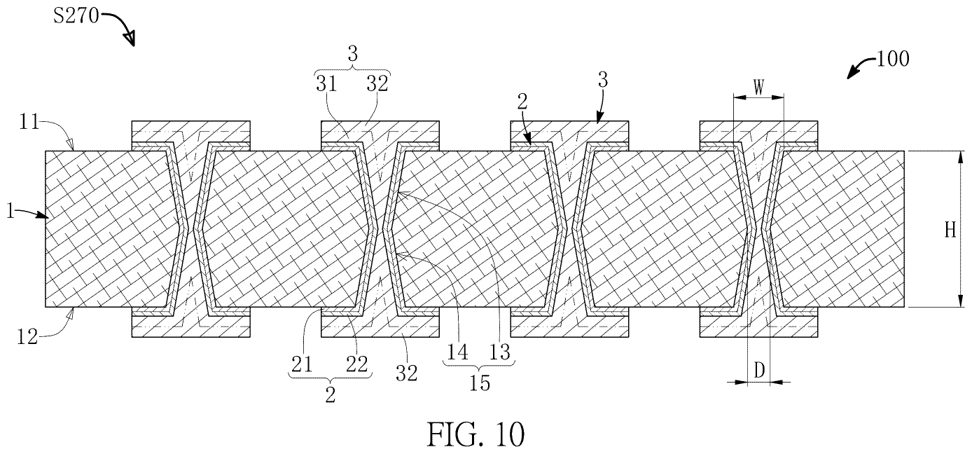

As shown in FIG. 10, the removing step S270 is implemented by removing the first shielding layer S1 and the second shielding layer S2, thereby obtaining a metallized ceramic circuit board 100.

### Beneficial Effects of the Embodiments

In conclusion, the metallized ceramic circuit board and the manufacturing method thereof provided by the present disclosure can use the ceramic substrate to be cooperated with the seed layer and the patterned circuit for replacing the conventional silicon substrate or the conventional glass substrate, thereby ensuring that the metallized ceramic circuit board can meet requirements of circuit layout and can effectively increase the heat-dissipation and bending resistance thereof.

Specifically, the metallized ceramic circuit board and the manufacturing method in the present disclosure can be provided with the ceramic substrate that has the first blind vias and the second blind vias, which are in cooperation with each other by having the truncated shapes, so as to enable the thru-holes having a high density arrangement to be formed in the ceramic substrate and enable the patterned circuit having a low line width and/or a low line spacing to be formed on the ceramic substrate.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a metallized ceramic circuit board, comprising:
a first drilling step implemented by laser-drilling a first surface of a ceramic substrate to form a plurality of first blind vias spaced apart from each other, wherein each of the plurality of first blind vias has a truncated shape that is tapered in a direction away from the first surface;
a second drilling step implemented by laser-drilling a second surface of the ceramic substrate to form a plurality of second blind vias that are spaced apart from each other and that respectively correspond in position to the plurality of first blind vias, wherein each of the plurality of second blind vias has a truncated shape that is tapered in a direction away from the second surface, and each of the plurality of second blind vias and a corresponding one of the plurality of first blind vias are in spatial communication with each other to be jointly defined as one of a plurality of thru-holes;
a formation step implemented by forming a seed layer on the first surface, the second surface, and a plurality of hole walls respectively defining the plurality of thru-holes;
a patterning step implemented by respectively forming a first shielding layer and a second shielding layer on two opposite sides of the seed layer, wherein a part of the seed layer formed on the plurality of hole walls is exposed from the first shielding layer and the second shielding layer; and
a direct plated copper (DPC) step implemented by electroplating the part of the seed layer to form a patterned circuit.

2. The manufacturing method according to claim 1, wherein the first blind via and the second blind via of each of the plurality of thru-holes are of a same truncated cone shape and are in a mirror-symmetrical arrangement.

3. The manufacturing method according to claim 1, wherein each of the plurality of thru-holes has a depth and a width that corresponds to the first surface, and the depth and the width of each of the plurality of thru-holes jointly define an aspect ratio that is greater than or equal to 10.

4. The manufacturing method according to claim 1, wherein the formation step includes:
a deposition step implemented by depositing a copper alloy layer on the first surface, the second surface, and the hole walls of the plurality of thru-holes; and
a chemical plating step implemented by chemical plating the copper alloy layer to form a copper layer, wherein the copper layer and the copper alloy layer are jointly defined as the seed layer.

5. The manufacturing method according to claim 1, wherein the DPC step includes:
a first copper plating step implemented by electroplating the part of the seed layer to form a first conductive layer, wherein each of the plurality of thru-holes is not fully filled with the first conductive layer, and the first blind via and the second blind via of each of the plurality of thru-holes are not in spatial communication with each other through the first conductive layer; and
a second copper plating step implemented by electroplating the first conductive layer to form a second conductive layer, wherein the first conductive layer and the second conductive layer are jointly defined as the patterned circuit.

6. A manufacturing method of a metallized ceramic circuit board, comprising:
a first drilling step implemented by laser-drilling a first surface of a ceramic substrate to form a plurality of first blind vias spaced apart from each other, wherein each of the plurality of first blind vias has a truncated shape that is tapered in a direction away from the first surface;
a second drilling step implemented by laser-drilling a second surface of the ceramic substrate to form a plurality of second blind vias that are spaced apart from each other and that respectively correspond in position to the plurality of first blind vias, wherein each of the plurality of second blind vias has a truncated shape that is tapered in a direction away from the second surface, and each of the plurality of second blind vias and a corresponding one of the plurality of first blind vias are in spatial communication with each other to be jointly defined as one of a plurality of thru-holes;
a formation step implemented by forming a seed layer on the first surface, the second surface, and a plurality of hole walls respectively defining the plurality of thru-holes;
a direct plated copper (DPC) step implemented by electroplating the seed layer to form a metal layer that is filled in an entirety of each of the plurality of thru-holes and that covers the first surface and the second surface;
a patterning step implemented by respectively forming a first shielding layer and a second shielding layer on two opposite sides of the metal layer, wherein a part of the metal layer filled in the entirety of each of the plurality of hole walls is covered by the first shielding layer and the second shielding layer; and
an etching step implemented by etching another part of the metal layer not covered by the first shielding layer and the second shielding layer to retain the part of the metal layer, which is defined as a patterned circuit.

7. The manufacturing method according to claim 6, wherein the first blind via and the second blind via of each of the plurality of thru-holes are of a same truncated cone shape and are in a mirror-symmetrical arrangement.

8. The manufacturing method according to claim 6, wherein each of the plurality of thru-holes has a depth and a width that corresponds to the first surface, and the depth and the width of each of the plurality of thru-holes jointly define an aspect ratio that is greater than or equal to 10.

9. The manufacturing method according to claim 6, wherein the formation step includes:
a deposition step implemented by depositing a copper alloy layer on the first surface, the second surface, and the hole walls of the plurality of thru-holes; and
a chemical plating step implemented by chemical plating the copper alloy layer to form a copper layer, wherein the copper layer and the copper alloy layer are jointly defined as the seed layer.

10. The manufacturing method according to claim 6, wherein the DPC step includes:
a first copper plating step implemented by electroplating the seed layer to form a first metal layer, wherein each of the plurality of thru-holes is not fully filled with the first metal layer, and the first blind via and the second blind via of each of the plurality of thru-holes are not in spatial communication with each other through the first metal layer; and
a second copper plating step implemented by electroplating the first metal layer to form a second metal layer, wherein the first metal layer and the second metal layer are jointly defined as the metal layer.

11. A metallized ceramic circuit board, comprising:
a ceramic substrate having a first surface and a second surface that is opposite to the first surface, wherein the ceramic substrate has:
a plurality of first blind vias recessed in the first surface and spaced apart from each other, wherein each of the plurality of first blind vias has a truncated shape that is tapered in a direction away from the first surface; and
a plurality of second blind vias recessed in the second surface and spaced apart from each other, wherein each of the plurality of second blind vias has a truncated shape that is tapered in a direction away from the second surface, and each of the plurality of second blind vias is in spatial communication with one of the plurality of first blind vias to be jointly defined as one of a plurality of thru-holes;
a seed layer covering and being formed on hole walls respectively defining the plurality of thru-holes; and
a patterned circuit formed on the seed layer in a direct plated copper (DPC) manner and filled in an entirety of each of the plurality of thru-holes.

12. The metallized ceramic circuit board according to claim 11, wherein the first blind via and the second blind via of each of the plurality of thru-holes are of a same truncated cone shape and are in a mirror-symmetrical arrangement.

13. The metallized ceramic circuit board according to claim 12, wherein, in each of the plurality of thru-holes, a connection region of the first blind via and the second blind via has an aperture that is within a range from 20 μm to 40 μm.

14. The metallized ceramic circuit board according to claim 6, wherein each of the plurality of thru-holes has a depth and a width that corresponds to the first surface, and the depth and the width of each of the plurality of thru-holes jointly define an aspect ratio that is greater than or equal to 10.

15. The metallized ceramic circuit board according to claim 14, wherein the width of each of the plurality of thru-holes is within a range from 50 μm to 70 μm.
